(19) United States
(12) Patent Application Publication
(10) Pub. No.: US 2011/0309416 A1
(43) Pub. Date: Dec. 22, 2011

(54) STRUCTURE AND METHOD TO REDUCE FRINGE CAPACITANCE IN SEMICONDUCTOR DEVICES

(75) Inventors: Tenko Yamashita, Kanagawa (JP); Bruce B. Doris, Brewster, NY (US)

(73) Assignee: INTERNATIONAL BUSINESS MACHINES CORPORATION, Armonk, NY (US)

(21) Appl. No.: 12/819,689

(22) Filed: Jun. 21, 2010

(51) Int. Cl. H01L 29/78; H01L 21/336

(52) U.S. Cl. 257/288; 438/300; 257/E29.255; 257/E21.409

(57) ABSTRACT

A method of forming a semiconductor device is provided that includes providing a gate structure on a semiconductor substrate that includes at a gate conductor. Forming a sacrificial material layer on at least the sidewall surfaces of the gate conductor, and forming a raised source region and a raised drain region on the semiconductor substrate, wherein the raised source region and the raised drain are separated from the gate conductor by the sacrificial material layer. The sacrificial material layer is removed to provide a void separating the gate structure from the raised source and drain regions. An encapsulating material layer is formed bridging the gate structure to each of the raised source region and the raised drain region to provide an air gap separating the gate structure from the raised source regions and the raised drain regions.

### BACKGROUND

The present disclosure relates to semiconductor devices and methods of forming semiconductor devices.

For more than three decades, the continued miniaturization of silicon metal oxide semiconductor field effect transistors (MOSFETs) has driven the worldwide semiconductor industry. Various showstoppers to continued scaling have been predicated for decades, but a history of innovation has sustained Moore's Law in spite of many challenges. However, there are growing signs today that metal oxide semiconductor transistors are beginning to reach their traditional scaling limits. Since it has become increasingly difficult to improve MOSFETs and therefore complementary metal oxide semiconductor (CMOS) performance through continued scaling, methods for improving performance without scaling have become critical.

### SUMMARY

In one embodiment, a semiconductor device is provided including a gate structure present on a surface of a semiconductor substrate, and a raised source region and a raised drain region present on the surface of the semiconductor substrate on opposing sides of the gate structure. An air gap is present between the gate structure and each of the raised source region and the raised drain region. The air gap separates an entire sidewall of the gate structure from the raised source region and the raised drain region.

In another aspect, a method of forming a semiconductor device is provided. In one embodiment, the method includes providing a gate structure on a first portion of a surface of a semiconductor substrate, wherein the gates structure includes at least one gate conductor. A sacrificial material layer is then formed on at least the sidewall surfaces of the at least one gate conductor of the gate structure. A raised source region and a raised drain region is formed on a second portion of the surface of the semiconductor substrate, wherein the raised source region and the raised drain are separated from the sidewall surfaces of the at least one gate conductor by the sacrificial material layer. The sacrificial material layer is then removed to provide a void separating the gate structure from each of the raised source region and the raised drain region. An encapsulating material layer is formed bridging the gate structure to each of the raised source region and the raised drain region to encapsulate the void and provide an air gap separating the gate structure from the raised source region and the raised drain region.

### DESCRIPTION OF THE DRAWINGS

The following detailed description, given by way of example and not intended to limit the invention solely thereto, will best be appreciated in conjunction with the accompanying drawings, wherein like reference numerals denote like elements and parts, in which:

FIG. 1 is a side cross-sectional view of forming gate structures on a surface of a semiconductor substrate, wherein at least one of the gates structures includes at least one gate conductor, in accordance with one embodiment of the present disclosure.

FIG. 2 is a side cross-sectional view of forming a sacrificial material layer on the gate structures and the exposed portions of the semiconductor substrates, in accordance with one embodiment of the present disclosure.

FIG. 3 is a side cross-sectional view depicting etching the sacrificial material layer so that a remaining portion of the sacrificial material layer is present on at least the sidewall surfaces of the at least one gate conductor of the gate structure, in accordance with one embodiment of the present disclosure.

FIG. 4 is a side cross-sectional view depicting forming source extension regions and drain extension regions in the semiconductor substrates on opposing sides of the gate structure and adjacent to the remaining portion of the sacrificial material layer that is present on the sidewalls of the gate structures, in accordance with one embodiment of the present disclosure.

FIG. 5 is a side cross-sectional view depicting activating the source extension region and the drain extension region, in accordance with one embodiment of the present disclosure.

FIG. 6 is a side cross-sectional view depicting forming raised source regions and raised drain regions on the semiconductor substrate, wherein the raised source regions and the raised drains are separated from the sidewall surfaces of the at least one gate conductor by the sacrificial material layer, in accordance with one embodiment of the present disclosure.

FIG. 7 is a side cross-sectional view depicting removing the dielectric cap from an upper surface of the gate structures, in accordance with one embodiment of the present disclosure.

FIG. 8 is a side cross-sectional view depicting forming a metal semiconductor alloy on an upper surface of each of the gate conductors of the gate structures, the raised source regions, and the raised drain regions, in accordance with one embodiment of the present disclosure.

FIG. 9 is a side cross-sectional view depicting removing the remaining portion of the sacrificial material layer to provide a void separating the gate structures from each of the raised source regions and the raised drain regions, in accordance with one embodiment of the present disclosure.

FIG. 10 is a side cross-sectional view depicting forming an encapsulating material layer bridging the gate structures to each of the raised source regions and the raised drain regions to encapsulate the void to provide an air gap separating the gate structures from the raised source regions and the raised drain regions, in accordance with one embodiment of the present disclosure.

### DETAILED DESCRIPTION

Detailed embodiments of the present invention are disclosed herein; however, it is to be understood that the disclosed embodiments are merely illustrative of the invention that may be embodied in various forms. In addition, each of the examples given in connection with the various embodiments of the invention are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

The embodiments of the present disclosure relate to methods for producing a semiconductor device, in which an air gap is present separating the sidewalls of the gate conductor of the gate structure to the semiconductor device from the raised source region and the raised drain region of the semiconductor device. A semiconductor device is an intrinsic semiconductor material that has been doped, i.e., into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentration in an extrinsic semiconductor determines the conductivity type of the semiconductor. A field effect transistor is a semiconductor device in which output current, i.e., source-drain current, is controlled by the voltage applied to a gate structure. A field effect transistor has three terminals, i.e., gate structure, source and drain. The gate structure is a structure used to control output current, i.e., flow of carriers in the channel, of a semiconducting device, such as a field effect transistor, through electrical or magnetic fields. The channel region is the region between the source and drain of the semiconductor device that becomes conductive when the semiconductor device is turned on. The source region is a doped region in the semiconductor device, in which majority carriers are flowing into the channel. The drain region is a doped region in semiconductor device located at the end of the channel region, in which carriers are flowing out of the semiconductor device through the drain region. The term “raised”, as used to described a raised source region and/or raised drain region, means that the semiconductor material of the raised source region and/or raised drain region of the semiconductor device has an upper surface that is vertically offset and above the upper surface of the semiconductor material, e.g., semiconductor substrate, that the channel region of the device is present. An “air gap” is a volume of a gas that has a dielectric constant of less than 2.0, as measured in at 1 atmospheric pressure (atm) at room temperature.

In one embodiment, the positioning of the air gap between at least the sidewall of the gate conductor of the gate structure and the sidewall of the raised source and drain regions reduces the fringe capacitance of the device when compared to similar semiconductor devices in which a solid dielectric material is separating the gate conductor of the gate structure from the raised source and drain regions. The fringe capacitance is a measurement of the capacitance formed between the gate conductor and the raised source and drain regions, in addition to the capacitance that is formed between the gate structure and the portion of the source and drain extension regions that extends under the spacer separating the gate structure from the raised source and drain regions.

Typically, a semiconductor device has a solid dielectric spacer that is present between and separating the gate structure and the raised source and drain regions, in which the solid dielectric spacers typically has a dielectric constant of 2.25 or greater, e.g., ranging from 3.9-7.5, as measured at room temperature at 1 atm. For example, a solid dielectric spacer composed of silicon nitride (Si₃N₄) has a dielectric constant of about 7.5 at room temperature and 1 atm. The high dielectric constant of the solid dielectric spacer creates a high capacitance between the gate conductor and the raised source and drain regions. In comparison, and in some embodiments, by replacing the solid dielectric spacer with an air gap having a dielectric constant of 2.0 or less, the present disclosure reduces the capacitance between the gate conductor and the raised source and drain regions, therefore reducing the fringe capacitance. For example, in comparison to a structurally identical structure having a dielectric spacer composed of silicon nitride, the structure disclosed herein in which the dielectric spacer is replaced with an air gap provides a 80% decrease in the fringe capacitance.

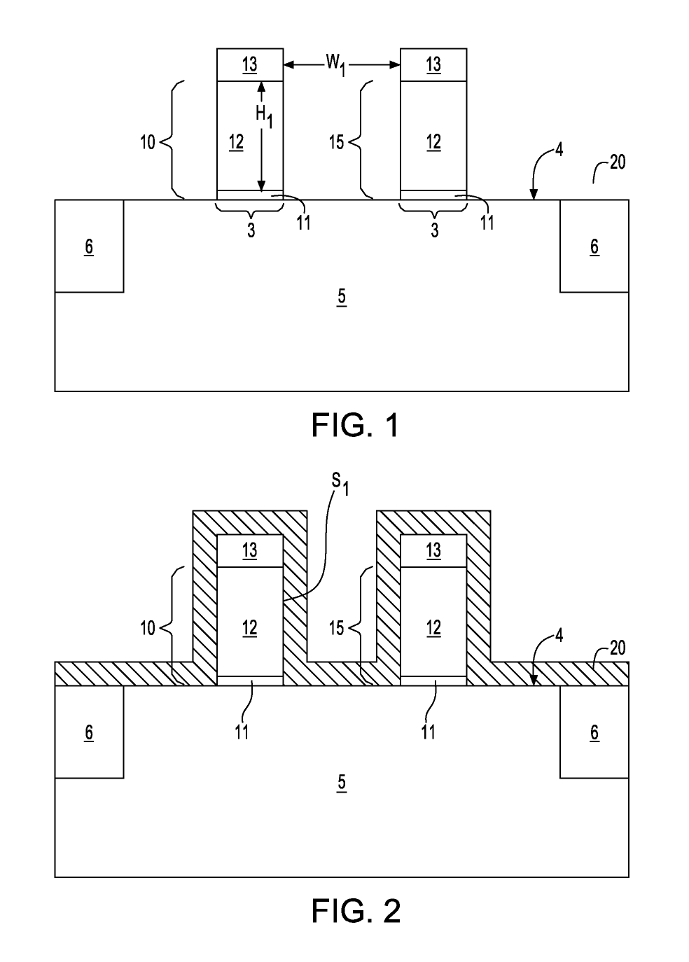

FIG. 1 depicts one embodiment of a first and second gate structure 10, 15 present on a semiconductor substrate 5. The first and second gate structures 10, 15 may provide the gate structures to semiconductor devices having the same conductivity type, or may provide the gate structures to semiconductor devices having opposing conductivity types. The term “conductivity type” denotes a dopant region, such as a source region and drain region, being p-type or n-type. In one embodiment, the semiconductor device including the first gate structure 10 may be processed to provide a p-type or an n-type field effect transistor, and the semiconductor device including the second gate structure 15 may be processed to provide a p-type or n-type semiconductor device, wherein the conductivity type of the semiconductor device having the first gate structure 10 is the same as the conductivity type of the semiconductor device having the second gate structure 15. In another embodiment, the semiconductor device including the first gate structure 10 may be processed to provide a p-type semiconductor device, such as a p-type field effect transistor, and the semiconductor device including the second gate structure 15 may be processed to provide an n-type semiconductor device, such as an n-type field effect transistor, in a complementary metal oxide semiconductor (CMOS) device arrangement. Although, two gate structures 10, 15 are depicted in FIG. 1, it is noted that the present disclosure is equally applicable to any number of gate structures 10, 15, including one, and any number of semiconductor devices, including one.

In one embodiment, the semiconductor substrate 5 may be a bulk semiconductor substrate, as depicted in FIG. 1. In one example, the bulk semiconductor substrate may be a silicon-containing material. Illustrative examples of Si-containing materials suitable for the bulk-semiconductor substrate include, but are not limited to, Si, SiGe, SiGeC, SiC, polysilicon, i.e., polySi, epitaxial silicon, i.e., epi-Si, amorphous Si, i.e., α:Si, and multi-layers thereof. Although silicon is the predominantly used semiconductor material in wafer fabrication, alternative semiconductor materials can be employed, such as, but not limited to, germanium, gallium arsenide, gallium nitride, silicon germanium, cadmium telluride and zinc sellenide.

Although not depicted in FIG. 1, the semiconductor substrate 5 may also be a semiconductor on insulator (SOI) substrate. In the embodiments, in which the semiconductor substrate 5 is an SOI substrate, the semiconductor substrate 5 is typically composed of at least a first semiconductor layer overlying a dielectric layer, i.e., buried dielectric layer, e.g., buried oxide layer. A second semiconductor layer may be present underlying the dielectric layer. The first semiconductor layer and second semiconductor layer may comprise any semiconducting material including, but not limited to: Si, strained Si, SiC, SiGe, SiGeC, Si alloys, Ge, Ge alloys, GaAs, InAs, and InP, or any combination thereof. The dielectric layer that is present underlying the first semiconductor layer and atop the second semiconductor layer may be formed by implanting a high-energy dopant into the semiconductor substrate 5 and then annealing the structure to form a buried oxide layer. In another embodiment, the dielectric layer may be deposited or grown prior to the formation of the first semiconductor layer. In yet another embodiment, the semiconductor on insulator (SOI) substrate may be formed using wafer-bonding techniques, where a bonded wafer pair is formed utilizing glue, adhesive polymer, or direct bonding.

In one embodiment, the semiconductor substrate 5 may include an isolation region 6. The isolation region 6 may be a trench formed into the semiconductor substrate 5 that is filled with an insulating material, such as an oxide, nitride, or oxynitride. In another embodiment, the isolation region 6 is a shallow trench isolation (STI) region. In a further embodiment, the shallow trench isolation region 6 may be formed by etching a trench in the semiconductor substrate 5 utilizing a dry etching process, such as reactive-ion etching (RIE) or plasma etching. In one embodiment, chemical vapor deposition or another like deposition process may be used to fill the trench with polysilicon or another like STI dielectric material, such as an oxide. A planarization process, such as chemical-mechanical polishing (CMP), may optionally be used to provide a planar structure. In some embodiments, the isolation region 6 may be a filed isolation oxide that is formed utilizing a local oxidation of semiconductor process.

Referring to FIG. 1, each of the first gate structure 10 and the second gate structure 15 include at least one gate dielectric 11 and at least one gate conductor 12. The first and second gate structures 10, 15 may be formed using deposition, photolithography and selective etch processes. A gate layer stack is formed on the semiconductor substrate 5 by depositing at least one gate dielectric layer 11 on the semiconductor substrate 5, and then by depositing at least one gate conductor layer 12 on the at least one gate dielectric layer 11.

The gate layer stack is then patterned and etched to provide the first and second gate structures 10, 15. Specifically, a pattern is produced by applying a photoresist to the surface to be etched, exposing the photoresist to a pattern of radiation, and then developing the pattern into the photoresist utilizing a resist developer. Once the patterning of the photoresist is completed, the sections covered by the photoresist are protected while the exposed regions are removed using a selective etching process that removes the unprotected regions. In some embodiments, the gate layer stack can be formed by a replacement gate process.

In one embodiment, a hard mask (hereafter referred to as a dielectric cap 13) may be used to form the first and second gate structures 10, 15. The dielectric cap 13 may be formed by first depositing a dielectric hard mask material, like SiN or SiO₂, atop a layer of gate conductor material and then applying a photoresist pattern to the hardmask material using a lithography process steps. The photoresist pattern is then transferred into the hard mask material using a dry etch process forming the dielectric cap 13. Next the photoresist pattern is removed and the dielectric cap 13 pattern is transferred into the gate conductor material during a selective etching process, which etches the gate stack to provide the first and second gate structure 10, 15.

In one embodiment, the at least one gate dielectric 11 of the first and second gate structures 10, 15 may be an oxide, nitride and oxynitrides of silicon. In another embodiment, the at least one gate dielectric 11 may be composed of a high-k dielectric material. A high-k dielectric material has a dielectric constant that is greater than the dielectric constant of silicon oxide (SiO₂). In one embodiment, a high-k dielectric material has a dielectric constant that is greater than 4.0. High-k dielectric materials that are suitable for the at least one gate dielectric 11 may include, but are not limited to, hafnium oxides, hafnium silicates, titanium oxides, barium-strontium-titantates (BSTs) and lead-zirconate-titanates (PZTs). The at least one gate dielectric 11 of the first gate structure 10 may be composed of the same material or different material than the at least one gate dielectric 11 of the second gate structure 15.

The at least one gate dielectric 11 may be formed using any of several deposition and growth methods, including but not limited to, thermal or plasma oxidation or nitridation methods, chemical vapor deposition methods and physical vapor deposition methods. The at least one gate dielectric 11 of the first gate structure 10 may be composed of the same material or different material as the at least one gate dielectric 11 of the second gate structure. Although the at least one gate dielectric 11 is depicted in the supplied figures as being a single layer, embodiments have been contemplated in which the at least one gate dielectric 11 of the first and second gate structures 10, 15 is a multi-layered structure of conductive materials. In one embodiment, the at least one gate dielectric 11 has a thickness ranging from 10 angstroms to 200 angstroms.

The at least one gate conductor 12 may be composed of conductive materials including, but not limited to, metals, metal alloys, metal nitrides and metal silicides, as well as laminates thereof and composites thereof. In one embodiment, the at least one gate conductor 12 may be any conductive metal including, but not limited to, W, Ni, Ti, Mo, Ta, Cu, Pt, Ag, Au, Ru, Ir, Rh, and Re, and alloys that include at least one of the aforementioned conductive elemental metals. The at least one gate conductor 12 may also comprise doped polysilicon and/or polysilicon-germanium alloy materials (i.e., having a dopant concentration from 1E18 to 1E22 dopant atoms per cubic centimeter) and polycide materials (doped polysilicon/metal silicide stack materials). The at least one gate conductor 12 of the first gate structure 10 may be composed of the same material or different material than the at least one gate conductor 12 of the second gate structure 15. The at least one gate conductor 12 may be formed using a deposition method including, but not limited to, salicide methods, atomic layer deposition methods, chemical vapor deposition methods and physical vapor deposition methods, such as, but not limited to, evaporative methods and sputtering methods. Although the at least one gate conductor 12 is depicted in the supplied figures as each being a single layer, embodiments have been contemplated in which the at least one gate conductor 12 is a multi-layered structure of conductive materials.

The height H1 of the at least one gate conductor 12 for each of the first and second gate structure 10, 15 may range from 15 nm to 50 nm. In one embodiment, the height H1 of the at least one gate conductor 12 may range from 20 nm to 40 nm. In another embodiment, the height H1 of the at least one gate conductor 12 may range from 25 nm to 35 nm. The width W1 separating the first gate structure 10 from the second gate structure 15 may range from 20 nm to 40 nm. In another embodiment, the width W1 separating the first gate structure 10 from the second gate structure 15 may range from 25 nm to 35 nm.

Still referring to FIG. 1, each of the first and second gate structures 10, 15 are formed on a surface 4 of the semiconductor substrate 5, which in some embodiments is provided by the upper surface of the semiconductor substrate 5. The portion of the surface 4 that each of the first and second gate structures 10, 15 are present on can be referred to as the first portion 3 of the surface 4 of the semiconductor substrate 5.

FIGS. 2 and 3 depict one embodiment of forming a sacrificial material layer 20 on at least the sidewall S₁ surfaces of the at least one gate conductor 12 of the first and second gate structures 10, 15. By “sacrificial” it is meant that this material layer is not present in the final structure of the semiconductor device, although it is employed to contribute to the definition of the geometry of the subsequently formed air gap. FIG. 2 depicts a blanket deposition of a sacrificial material layer 20 on the first and second gate structures 10, 15 and the exposed portions of the surface 4 of the semiconductor substrate 5 that is between the first and second gate structures 10, 15. In one embodiment, the sacrificial material layer 20 is formed on the sidewalls of the gate structures 10, 15, including the sidewalls surfaces S₁ of the at least one gate conductor 12, and the sacrificial material layer 20 is formed on the upper surface of the gate structures 10, 15.

The sacrificial material layer 20 may be a dielectric material, such as an oxide, nitride or oxynitride material. In one embodiment, in which the sacrificial material layer 20 is an oxide, the sacrificial material layer 20 is composed of silicon oxide. In another embodiment, in which the sacrificial material layer 20 is a nitride, the sacrificial material layer 20 is silicon nitride. It is noted that the above compositions are provided for illustrative purposes only, because the sacrificial material layer 20 may be any material that can be removed selectively to the dielectric cap 13 of the first and second gate structure 10, 15, and the surface 4 of the semiconductor substrate 5.

The sacrificial material layer 20 may be deposited using chemical vapor deposition (CVD). Chemical vapor deposition (CVD) is a deposition process in which a deposited species is formed as a result of chemical reaction between gaseous reactants at greater than room temperature (25° C. to 900° C.); wherein solid product of the reaction is deposited on the surface on which a film, coating, or layer of the solid product is to be formed. Variations of CVD processes include, but not limited to, Atmospheric Pressure CVD (APCVD), Low Pressure CVD (LPCVD) and Plasma Enhanced CVD (EPCVD), Metal-Organic CVD (MOCVD) and combinations thereof may also be employed. Other deposition methods that are suitable for depositing the sacrificial material layer 20 include, but are not limited to: spinning from solution, spraying from solution, chemical sputter deposition, reactive sputter deposition, ion-beam deposition, and evaporation.

In one embodiment, the sacrificial material layer 20 is deposited using a conformal deposition process. The term “conformal” denotes a layer having a thickness that does not deviate from greater than or less than 20% of an average value for the thickness of the layer. The thickness of the sacrificial material layer 20 may range from 1 nm to 25 nm. In one embodiment, the thickness of the sacrificial material layer 20 ranges from 5 nm to 10 nm.

FIG. 3 depicts one embodiment of etching the sacrificial material layer 20 so that a remaining portion of the sacrificial material layer 20′ is present on at least the sidewall S₁ surfaces of the at least one gate conductor 12 of the first and second gate structures 10, 15. The sacrificial material layer 20 is typically etched with an anistropic etch. An anisotropic etch process is a material removal process in which the etch rate in the direction normal to the surface to be etched is greater than in the direction parallel to the surface to be etched. The anisotropic etch may include reactive-ion etching (RIE). Reactive ion etching (RIE) is a form of plasma etching in which during etching the surface to be etched is placed on the RF powered electrode. Moreover, during RIE the surface to be etched takes on a potential that accelerates the etching species extracted from a plasma toward the surface, in which the chemical etching reaction is taking place in the direction normal to the surface. Other examples of anisotropic etching that can be used at this point of the present invention include ion beam etching, plasma etching or laser ablation.

Due to the anisotropic nature of the etch, the portions of the sacraficial material layer 20 that are horizontally orientated, such as the portions of the sacraficial material layer 20 that are present on the dielectric cap 13 and the surface 4 of the semiconductor substrate 5 are removed prior to the portions of the sacraficial material layer 20 that are vertically orientated, such as the portions of the sacraficial material layer 20 that are present on the sidewalls S₁ of the at least one gate conductor 12. The anisotropic etch may recess the vertically orientated portions of the sacraficial material layer 20 are present on the sidewalls S₁ of the at least one gate conductor 12. In one example, the anisotropic etch step is continued until the upper surface of the dielectric cap 13 and the surface 4 of the semiconductor substrate 5 that is not immediately adjacent to the first and second gate structure 10, 15 are exposed. The portion of the surface 4 of the semiconductor substrate 5 that is immediately adjacent to the first and second gate structure 10, 15 is under the remaining portion of the sacraficial material layer 20′.

In one example, the remaining portion of the sacraficial material layer 20′ that is composed of silicon nitride has a width W2 ranging from 1 nm to 20 nm. In another example, the remaining portion of the sacraficial material layer 20′ that is composed of silicon nitride has a width W2 ranging from 5 nm to 15 nm. In yet another example, the remaining portion of the sacraficial material layer 20′ that is composed of silicon nitride has a width W2 ranging from 5 nm to 10 nm.

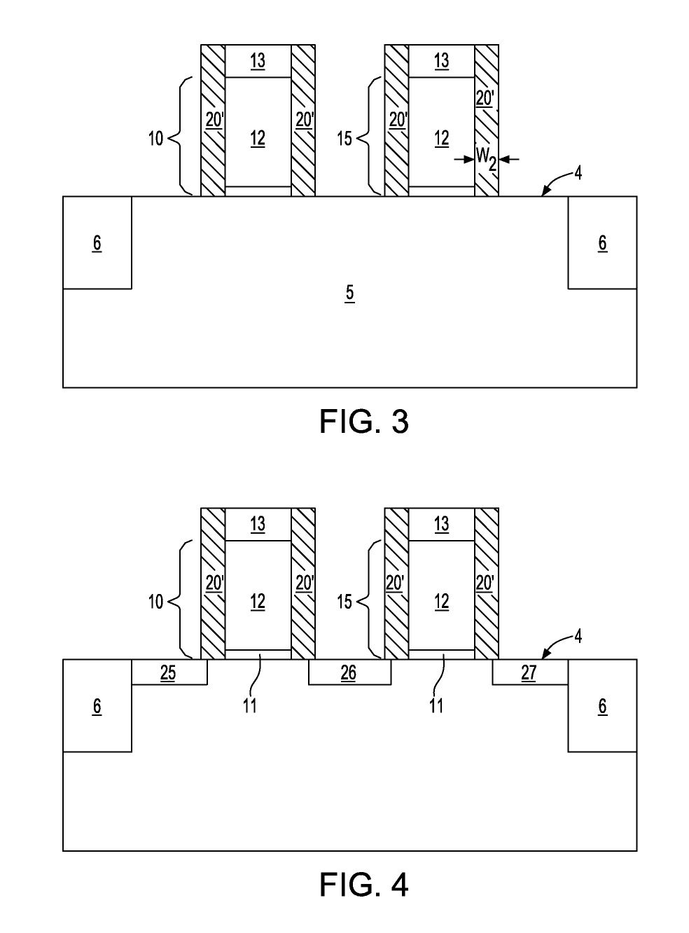

FIG. 4 depicts one embodiment of forming a source extension region 25 and a drain extension region 26 in the semiconductor substrate 5 on opposing sides of the first and second gate structures 10, 15 and adjacent to the remaining portion of the sacrificial material layer 20′. FIG. 4 depicts that a shared source and drain extension region 27 is present between the first gate structure 10 and the second gate structures 15. The shared source and drain extension region 27 provides the drain extension region of the device having the first gate structure 10, and the source extension region of the device having the second gate structure 15. It is noted that the shared source and drain extension region 27 may be replaced with a drain extension region for the semiconductor device having the first gate structure 10 that is separate from the source extension region for the semiconductor device having the second gate structure 15. In this embodiment, the drain extension region of the semiconductor device having the first gate structure 10 is separated from the source extension region of the semiconductor device having the second gate structure 15 by an isolation region, such as a shallow trench isolation (STI) region.

In one embodiment, the source and drain extension regions 25, 26, 27 are ion implanted into the exposed portion of the semiconductor substrate 5 that is not underlying the remaining sacrificial material layer 20′ or the first and second gate structure 10, 15. The ion implantation step that provides the source and drain extension regions 25, 26, 27 may include a combination of normally incident and angled implants to form the desired grading in the extensions. For producing n-type field effect transistor (NFET) devices, group V elements from the Periodic Table of Elements are implanted into a semiconductor substrate 5 that is composed of a group IV element of the periodic table of elements. Implant energies for forming source and drain extension regions 25, 26, 27 comprised of arsenic typically range from 1 keV to 5 keV. Implant energies for forming source and drain extension regions 25, 26, 27 comprised of BF₂ typically range from 1 keV to 7 keV. Implant energies for forming source and drain extension regions 25, 26, 27 comprised of boron range from 1 keV to 2 keV. These implants are typically carried out using a low concentration of dopant dose ranging from 4×10¹⁴ atoms/cm² to 2×10¹⁵ atoms/cm².

In the embodiments, in which the semiconductor device having the first gate structure 10 and the semiconductor device having the second gate structure 15 are of the same conductivity type, as depicted in FIG. 4, a single ion implantation may provide the source and drain extension regions 25, 26, 27. In another embodiment, in which the semiconductor device having the first gate structure 10 has an opposite conductivity as the semiconductor device having the second gate structure 15, selective implantation of the dopant species for the source and drain extension regions may be provided using a block mask. For example, a first region of the semiconductor device containing the first gate structure 10 may be protected by a first block mask, while a second region of the semiconductor substrate 5 having the second gate structure 15 is implanted to provide source and drain extensions regions of a first conductivity type, such as n-type or p-type conductivity. The first block mask is then removed. Thereafter, the second region of the semiconductor substrate having the source and drain extension regions of the first conductivity is protected by a second block mask, while the first region having the first gate structure 10 is implanted to provide source and drain extension regions of a second conductivity, such as n-type or p-type conductivity, wherein the first conductivity is different, i.e., opposite, than the second conductivity. For example, the first conductivity dopant may be n-type, and the second conductivity dopant may be p-type.

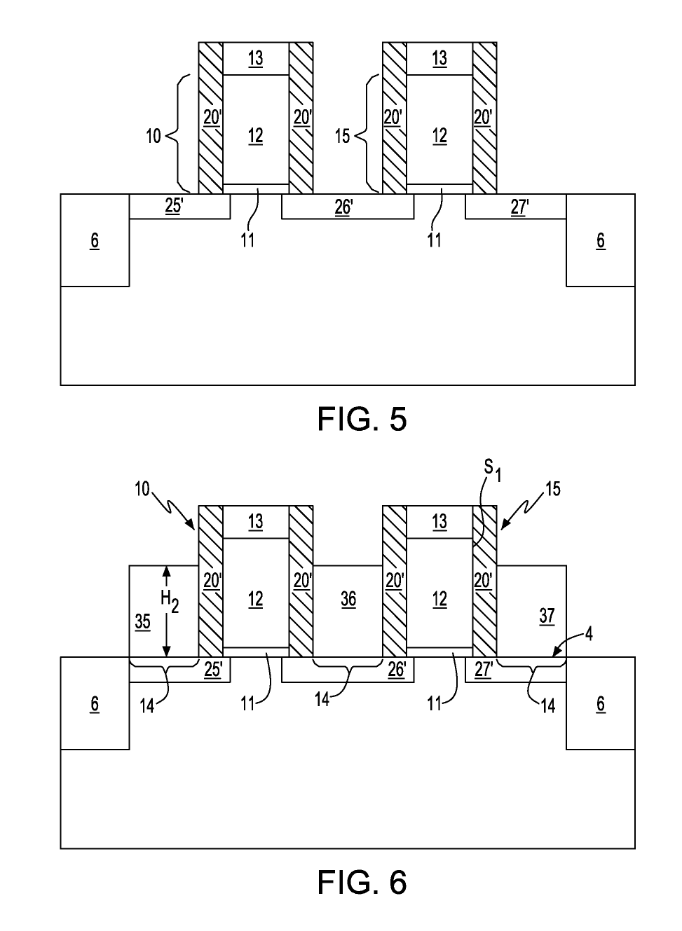

FIG. 5 depicts activating the source and drain extension regions 25′, 26′, 27′. In one embodiment, the source and drain extension regions 25′, 26′, 27′ may be activated using a thermal anneal. The anneal process may be provided by thermal anneal, such as a furnace anneal, rapid thermal anneal or laser anneal. In one example, the temperature of the anneal process to activate the dopant of the source and drain extension regions 25′, 26′, 27′ ranges from 700° C. to 1100° C. In another example, the temperature of the anneal process to activate the dopant of the source and drain extension regions 25′, 26′, 27′ ranges from 800° C. to 1000° C. The time period of the anneal process to activate the dopant of the source and drain extension regions 25′, 26′, 27′ ranges from 10 mili-seconds to 30 seconds. In another embodiment, the time period of the anneal process to activate the dopant of the source and drain extension regions 25′, 26′, 27′ ranges from 10 mili-seconds seconds to 10 seconds.

During the activation anneal, the dopant of the source and drain extension regions 25′, 26′, 27′ may diffuse through the semiconductor substrate 5. In one embodiment, the dopant of the source and drain extension regions 25′, 26′, 27′ laterally diffuses to extend the source and drain extension regions to underlie at least a portion of the first and second gate structures 10, 15.

FIG. 6 depicts one embodiment of forming a raised source region 35, a shared raised source and drain region 37, and a raised drain region 36 on a second portion 14 of the surface 4 of the semiconductor substrate 5. FIG. 6 depicts that a shared raised source and drain region 37 is present between the first gate structure 10 and the second gate structures 15. The shared raised source and drain region 37 provides the raised drain region of the device having the first gate structure 10, and the raised source region of the device having the second gate structure 15. It is noted that the shared raised source and drain extension region 37 may be replaced with a raised drain region for the semiconductor device having the first gate structure 10 that is separate from the raised extension region for the semiconductor device having the second gate structure 15. In this embodiment, the drain extension region of the semiconductor device having the first gate structure 10 is separated from the source extension region of the semiconductor device having the second gate structure 15 by an isolation region, such as a dielectric spacer, e.g., solid dielectric spacer or a void.

The second portion 14 that the raised source and drain regions 35, 36, 37 are present on may be the exposed upper surface, i.e., surface 4, of the semiconductor substrate 5 that is not present under the first gate structure 10, the second gate structure 15, and the remaining portion of the sacrificial layer 20′. In one embodiment, the raised source and drain regions 35, 36, 37 are on opposing sides of the first and second gate structures 10, 15, but are separated from the sidewalls, e.g., sidewalls S₁ of the at least one gate conductor 12, of the first and second gate structures 10, 15 by the remaining portion of the sacrificial material layer 20′.

In one embodiment, the raised source and drain regions 35, 36, 37 are formed using an epitaxial deposition process. As used herein, the terms “epitaxially formed”, “epitaxial growth” and/or “epitaxial deposition” mean the growth of a semiconductor material on a deposition surface of a semiconductor material, in which the semiconductor material being grown has the same crystalline characteristics as the semiconductor material of the deposition surface. When the chemical reactants are controlled and the system parameters set correctly, the depositing atoms arrive at the surface 4 of the semiconductor substrate 5 with sufficient energy to move around on the surface and orient themselves to the crystal arrangement of the atoms of the deposition surface. Thus, an epitaxial film deposited on a {100} crystal surface will take on a {100} orientation. If, on the other hand, the wafer surface has an amorphous surface layer, possibly the result of implanting, the depositing atoms have no surface to align to, resulting in the formation of polysilicon instead of single crystal silicon.

The raised source and drain regions 35, 36, 37 may be provided by selective growth of silicon. The silicon may be single crystal, polycrystalline or amorphous. The raised source and drain regions 35, 36, 37 may be epitaxial silicon. The raised source and drain regions 35, 36, 37 may also be provided by selective growth of germanium. The germanium may be single crystal, polycrystalline or amorphous. In another example, the raised source and drain regions 35, 36, 37 may be composed of SiGe.

A number of different sources may be used for the selective deposition of silicon. Silicon sources for growth of silicon (epitaxial or poly-crystalline) include silicon tetrachloride, dichlorosilane (SiH₂Cl₂), and silane (SiH₄). The temperature for epitaxial silicon deposition typically ranges from 550° C. to 900° C. Higher temperature typically results in faster deposition; the faster deposition may result in crystal defects and film cracking.

In one embodiment, the raised source and drain regions 35, 36, 37 may be provided by selective-epitaxial growth of SiGe atop the second portion 14 of the semiconductor substrate 5. The Ge content of the epitaxial grown SiGe may range from 5% to 50%, by atomic weight %. In another embodiment, the Ge content of the epitaxial grown SiGe may range from 10% to 20%. The epitaxial grown SiGe may be under an intrinsic compressive strain, in which the compressive strain is produced by a lattice mismatch between the larger lattice dimension of the SiGe and the smaller lattice dimension of the layer on which the SiGe is epitaxially grown. In one embodiment, the epitaxial grown SiGe produces a compressive strain in the channel region of a p-type semiconductor device, such as a pFET device.

In another embodiment, the raised source and drain regions 35, 36, 37 are composed of epitaxially grown Si:C (silicon doped with carbon). The carbon (C) content of the epitaxial grown Si:C ranges from 1% to 5%, by atomic weight %. In another embodiment, the carbon (C) content of the epitaxial grown Si:C may range from 1% to 2.5%. The epitaxial grown Si:C may be under an intrinsic tensile strain, in which the tensile strain is produced by a lattice mismatch between the smaller lattice dimension of the Si:C and the larger lattice dimension of the layer on which the Si:C is epitaxially grown. In one embodiment, the epitaxial grown Si:C produces a tensile strain in the channel region of an n-type semiconductor device, such as a nFET device.

In one embodiment, the raised source and drain regions 35, 36, 37 have a height H₂ ranging from 5 nm to 30 nm, as measured from the surface 4 of the semiconductor substrate 5. In another embodiment, each of the raised source and drain regions 35, 36, 37 has a height H₂ ranging from 5 nm to 25 nm, as measured from the surface 4 of the semiconductor substrate 5. In yet another embodiment, the raised source and drain regions 35, 36, 37 have a height H₂ ranging from 10 nm to 20 nm, as measured from the surface 4 of the semiconductor substrate 5.

In one embodiment, the raised source and drain regions 35, 36, 37 are in-situ doped with a p-type conductivity dopant during the epitaxial growth process. P-type semiconductor devices, e.g., pFETs, are produced by doping the raised source and drain regions 35, 36, 37 with elements from group III of the Periodic Table of Elements. In one embodiment, the group III element is boron, aluminum, gallium or indium. In one example, in which the raised source and drain regions 35, 36, 37 are doped to provide a p-type conductivity, the dopant may be boron present in a concentration ranging from 1×10¹⁹ atoms/cm³ to about 5×10²⁰ atoms/cm³. In another embodiment, the p-type conductivity dopant may be introduced to the raised source and drain regions 35, 36, 37 using ion implantations following the epitaxial growth process that deposits the semiconductor material of the raised source and drain regions 35, 36, 37.

In one embodiment, the raised source and drain regions 35, 36, 37 are doped with an n-type conductivity dopant during the epitaxial growth process. N-type semiconductor devices, e.g., nFETs, are produced by doping the raised source and drain regions 35, 36, 37 with elements from group V of the Periodic Table of Elements. In one embodiment, the group V element is phosphorus, antimony or arsenic. In one example, in which the raised source and drain regions 35, 36, 37 are doped to provide a p-type conductivity, the dopant may be boron present in a concentration ranging from 1×10²⁰ atoms/cm³ to about 5×10²¹ atoms/cm³. In another embodiment, the n-type conductivity dopant may be introduced to the raised source and drain regions 35, 36, 37 using ion implantations following the epitaxial growth process that deposits the semiconductor material of the raised source and drain regions 35, 36, 37.

In one embodiment, the dopant of the raised source and drain regions 35, 36, 37 are activated using a thermal anneal. The thermal anneal process may be provided by a furnace anneal, rapid thermal anneal or laser anneal. In one example, the temperature of the anneal process to activate the dopant of the raised source and drain regions 35, 36, 37 ranges from 1100° C. to 1400° C. In another examples, the temperature of the anneal process to activate the dopant of the raised source and drain regions 35, 36, 37 ranges from 1200° C. to 1350° C. The time period of the anneal process to activate the dopant of the raised source and drain regions 35, 36, 37 ranges from 10 mili-seconds to 60 seconds. In another embodiment, the time period of the anneal process to activate the dopant of the raised source and drain regions 35, 36, 37 ranges from 10 mili-seconds to 30 seconds.

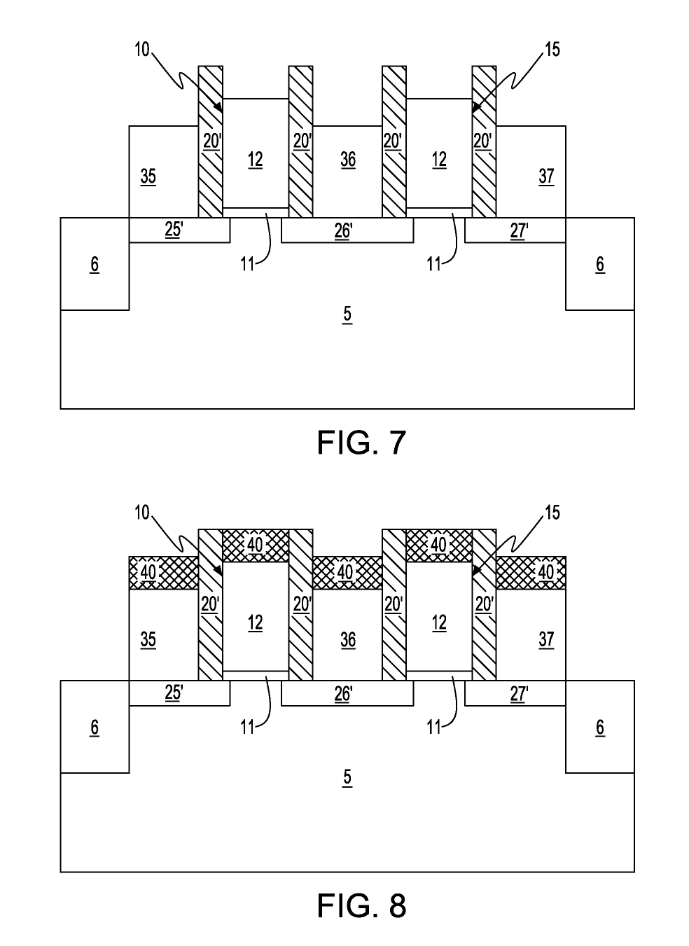

FIG. 7 depicts one embodiment of removing the dielectric cap 13 from an upper surface of the first and second gate structures 10, 15. In one embodiment, removing the dielectric cap 13 exposes the upper surface of the at least one conductive layer 12 of the first and second gate structure 10, 15. In one embodiment, the dielectric cap 13 is removed using a selective etch process. As used herein, the term “selective” in reference to a material removal process denotes that the rate of material removal for a first material is greater than the rate of removal for at least another material of the structure to which the material removal process is being applied. In one embodiment, the selective etch process removes the dielectric cap 13 selective to the at least one gate conductor 12 and the raised source and drain regions 35, 36, 37. In one embodiment, in which the dielectric cap 13 is composed of silicon oxide (SiO₂), the dielectric cap is removed by a wet etch composed of hydrofluoric acid (HF).

FIG. 8 depicts forming a metal semiconductor alloy 40 on an upper surface of each of the at least one gate conductor 12 of the first and second gate structure 10, 15, and the raised source and drain region 35, 36, 37. In some embodiments, the metal semiconductor alloy 40 is a silicide or germanide. Silicide formation typically requires depositing a refractory metal, such as Ni or Ti, onto the surface of a Si-containing material, such as polysilicon. Following deposition, the structure is then subjected to an annealing step including, but not limited to, rapid thermal annealing. During thermal annealing, the deposited metal reacts with silicon forming a metal silicide. Examples of silicides suitable for the metal semiconductor alloy 40 include, but are not limited to, nickel silicide, nickel platinum silicide, cobalt silicide, tantalum silicide, and titanium silicide. Germanide formation typically requires depositing a refractory metal, such as Ni or Ti, onto the surface of a Ge-containing material. During thermal annealing, the deposited metal reacts with germanium forming a germicide. In some embodiments, the metal semiconductor alloy regions 40 may be omitted.

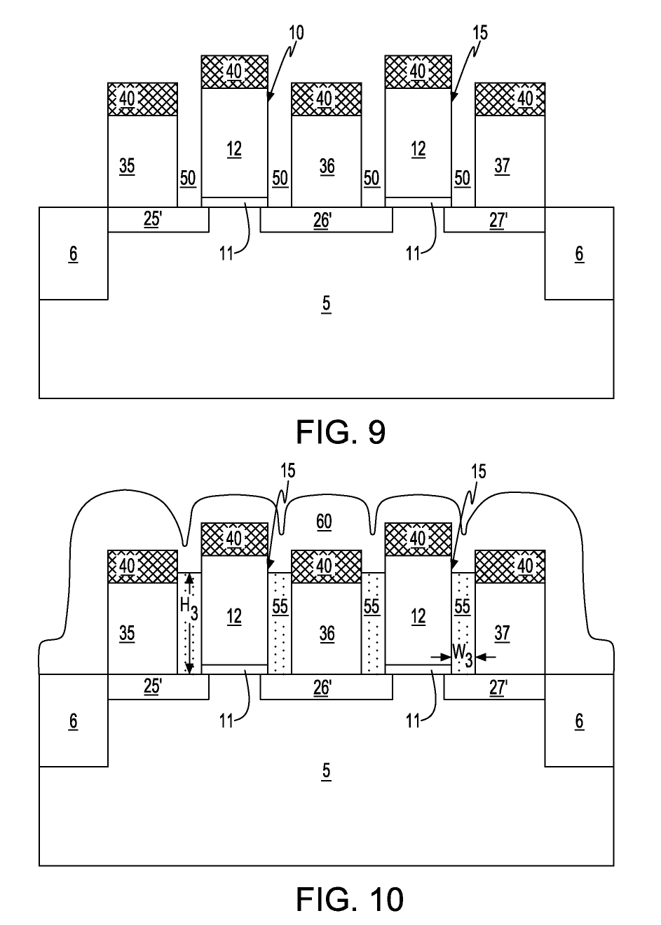

FIG. 9 depicts removing the remaining portion of the sacrificial material layer 20′ to provide a void 50 separating the first and second gate structure 10, 15 from each of the raised source and drain regions 35, 36, 37. In one embodiment, the remaining portion of the material layer 20′ is removed by a selective etch process. In one embodiment, the etch process for removing the sacrificial material layer 20′ is selective to the metal semiconductor alloy 40 and the semiconductor substrate 5. In one embodiment, the etch process for removing the sacrificial material layer 20′ is an anisotropic etch, such as reactive ion etch or laser etching. By removing the sacrificial material layer 20′, a void 50 is produced separating the sidewall of the first and second gate structures 10, 15, i.e., the sidewall S1 of the at least one gate conductor 12 of the first and second gate structures 10, 15, from the sidewall of the raised source and drain regions 35, 36, 37. In one embodiment, the void 50 has the same sidewall geometry and width as the remaining portion of the sacrificial material layer 20′.

FIG. 10 depicts one embodiment of forming an encapsulating material layer 60 bridging from each of the first and second gate structures 10, 15 to the adjacent raised source and drain regions 35, 36, 37 to encapsulate the void 50 and provide an air gap 55. The air gap 55 is an enclosed gas filled void having a dielectric constant of 2.0 or less. In one embodiment, the air gap 55 is a gas filled void having a dielectric constant of 1.5 or less. In yet another embodiment, the air gap 55 has a dielectric constant of 1.05 or less. In one example, the air gap 55 has a dielectric constant of 1.0. The aforementioned dielectric constants are measured at approximately 1 atm at room temperature, i.e., 20° C. to 25° C.

The air gap 55 separates each of the first and second gate structures 10, 15 from the raised source and drain regions 35, 36, 37. In one embodiment, the air gap 55 separates the entire sidewall of the first and second gates structure 10, 15 from the entire sidewall of the raised source and drain regions 35, 36, 37. The volume of the air gap 55 is defined by the width W3 separating the sidewall of the first and second gate structures 10, 15 from the sidewall of the raised source and drain regions 35, 36, 37, and the height H3 separating the surface 4 of the semiconductor substrate 5 from the portion of the encapsulating material layer 60 that is bridging across the void from the upper surface of the gate structures 10, 15 to the upper surface of the raised source and drain regions 35, 36, 37.

In one example, the width W3 of the air gap 55 ranges from 1 nm to 20 nm. In another example, the width W3 of the air gap 55 ranges from 5 nm to 15 nm. In yet another example, the width W3 of the air gap 55 ranges from 5 nm to 10 nm. The height H3 of the air gap 55 may range from 15 nm to 50 nm. In one embodiment, the height H3 of the air gap 55 may range from 20 nm to 40 nm. In another embodiment, the height H3 of the air gap 55 may range from 25 nm to 35 nm. In one embodiment, the aspect ratio air gap, i.e., ratio of height to width, is greater than 2.5.

The air gap 55 may be comprised of a gas from the ambient air. In one example, the dielectric constant of air at 1 atm is 1.00059. In another example, the dielectric constant of air at 100 atm is 1.0548. In yet another example, in which the air gap 55 is composed of oxygen gas (O₂), the dielectric constant of oxygen gas (O₂) at 20° C. (approximately room temperature) is 1.000494. In a further example, in which the air gap 55 is composed of hydrogen gas (H₂), the dielectric constant of hydrogen gas (H₂) is 1.000284 (at 100° C.). In another example, in which the air gap 55 is composed of carbon dioxide gas (CO₂), the dielectric constant of carbon dioxide (CO₂) at 20° C. is less than 1.5. In another example, in which the air gap 55 is composed of nitrogen gas (N₂), the dielectric constant of nitrogen gas (N₂) at 20° C. is 1.000580. In an even further example, in which the air gap 55 is composed of helium, the dielectric constant of helium at 15° C. is 1.055. It is noted that the above gas compositions for the air gap 55 are for illustrative purposes only. Any number of gas compositions may be selected so long as the dielectric constant of the gas is less than 2.0 at room temperature at 1 atm.

In one embodiment, the encapsulating material layer 60 (also referred to as a bridging material layer) may be formed on an upper surface of the metal semiconductor alloy 40 that is present on the first and second gate structures 10, 15 extending across the width W3 of the void 50 to the metal semiconductor alloy 40 that is present on the upper surface of the raised source and drain regions 35, 36, 37. In another embodiment, in which the metal semiconductor alloy regions 40 are omitted, the encapsulating material layer 60 (also referred to as a bridging material layer) may be formed on an upper surface of the first and second gate structures 10, 15 extending across the width W3 of the void 50 to the upper surface of the raised source and drain regions 35, 36, 37.

The encapsulating material layer 60 may be composed of any dielectric material that can extend from the upper surface of the gate structure 10, 15 to the upper surface of the raised source and drain regions 35, 36, 37. In one embodiment, the encapsulating material layer 60 includes, but is not limited to, an oxide, nitride, oxynitride and/or silicates including metal silicates, aluminates, titanates and nitrides. In one example, when the encapsulating material layer 60 is comprised of an oxide, the oxide may be selected from the group including, but not limited to, SiO₂, HfO₂, ZrO₂, Al₂O₃, TiO₂, La₂O₃, SrTiO₃, LaAlO₃, Y₂O₃ and mixture thereof. In another embodiment, the encapsulating material layer 60 is composed of a nitride, such as silicon nitride. The physical thickness of the encapsulating material layer 60 may vary, but typically, the encapsulating material layer 60 has a thickness ranging from 5 nm to 60 nm. In another embodiment, the encapsulating material layer 60 has a thickness ranging from 15 nm to 30 nm.

The encapsulating material layer 60 may be formed by a deposition process such as, for example, chemical vapor deposition (CVD), plasma-assisted CVD, metal organic chemical vapor deposition (MOCVD), atomic layer deposition (ALD), evaporation, reactive sputtering, chemical solution deposition and other like deposition processes. In one example, the encapsulating material layer 60 is composed of silicon nitride (Si₃N₄) deposited by plasma enhanced chemical vapor deposition using precursor gasses including SiH₄, NH₃, and N₂ at a pressure ranging from 2 Tor to 5 Tor at a temperature ranging from 400° C. to 480° C. It is noted that the above deposition processes are provided for illustrative purposes only, and are not intended to limit the present disclosure, as the encapsulating material layer 60 may be formed using any deposition method that does not fill the void.

Back end of the line (BEOL) processing including interlevel dielectric formation may following the formation of the encapsulating material layer 60. Further interconnects may be formed in electrical communication with the raised source and drain regions 35, 36, 37 and the first and second gate structures 10, 15.

While this invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of forming a semiconductor device comprising:
providing a gate structure on a first portion of a surface of a semiconductor substrate, wherein the gate structure includes at least one gate conductor;
forming a sacrificial material layer on at least the sidewall surfaces of the at least one gate conductor of the gate structure;
forming a raised source region and a raised drain region on a second portion of the surface of the semiconductor substrate, wherein the raised source region and the raised drain region are separated from the sidewall surfaces of the at least one gate conductor by the sacrificial material layer;
removing the sacrificial material layer to provide a void separating the gate structure from each of the raised source region and the raised drain region; and
forming an encapsulating material layer bridging the gate structure to each of the raised source region and the raised drain region to encapsulate the void, which provides an air gap separating the gate structure from the raised source region and the raised drain region.

2. The method of claim 1, wherein the providing of the gate structure comprises forming at least one gate dielectric layer on the surface of the semiconductor surface, forming at least one gate conductor layer on the at least one gate dielectric layer, and forming at least one dielectric cap layer on the at least one gate conductor layer to provide a gate stack; forming a first etch mask on the gate stack, wherein the first etch mask is overlying the first portion of the surface of the semiconductor substrate; and etching the gate stack selective to the first etch mask.

3. The method of claim 1, wherein the forming of the sacrificial material layer comprises depositing the sacrificial material layer on an upper surface of the gate structure, the sidewall surfaces of the gate structure, and a first exposed portion of the surface of the semiconductor substrate, and etching the sacrificial material layer so that a remaining portion of the sacrificial material layer is present on the sidewalls of the gate structure.

4. The method of claim 3 further comprising forming a source extension region and a drain extension region in the semiconductor substrate adjacent to the remaining portion of the sacrificial material layer that is present on the sidewalls of the gate structure.

5. The method of claim 4, wherein the forming of the source extension region and the drain extension region comprises ion implantation of an n-type or p-type dopant.

6. The method of claim 1, wherein the forming of the raised source region and the raised drain region on the second portion of the surface of the semiconductor substrate comprises epitaxial growth of a semiconductor material, wherein the second portion of the surface of the semiconductor substrate is an exposed portion of the semiconductor substrate that is not underlying the gate structure and the sacrificial material layer.

7. The method of claim 6, wherein the second portion of the surface of the semiconductor substrate that the raised source and drain regions comprise a source extension region and a drain extension region that are present on opposing sides of the gate structure.

8. The method of claim 6, wherein the raised source region and raised drain region are doped with a conductivity type dopant that is the same as the source extension region and the drain extension region, wherein the raised source and drain regions are in-situ doped during epitaxial growth, are doped using ion implantation, or are doped using a combination of epitaxial growth in-situ doping and ion implantation.

9. The method of claim 1 further comprising forming a metal semiconductor alloy region on an upper surface of the gate structure, the raised source region, and the raised drain region.

10. The method of claim 1, wherein the removing the sacrificial material layer to provide the void comprises an etch process that is selective to the gate structure, the semiconductor substrate, the raised source region, and the raised drain region.

11. The method of claim 1, wherein the void has a width ranging from 1 nm to 10 nm, as measured from the sidewall of the at least one gate conductor to a sidewall of one of the raised source region or the raised drain region.

12. The method of claim 1, wherein the forming of the encapsulating material layer bridging the gate structure to each of the raised source region and the raised drain region comprises deposition of a dielectric material extending from the upper surface of the gate structure to each of the raised source region and the raised drain region, wherein the dielectric material is not in direct contact with at least the sidewalls of the at least one gate conductor.

13. The method of claim 1, wherein the dielectric material is silicon nitride deposited by plasma enhanced chemical vapor deposition (PECVD) at a temperature ranging from 400° C. to 480° C. and a pressure ranging from 2 Tor to 5 Tor.

14. The method of claim 1, wherein the air gap comprises a gas having a dielectric constant of 1.5 or less.

15. A semiconductor device comprising:
a gate structure present on a surface of a semiconductor substrate;
a raised source region and a raised drain region present on the surface of the semiconductor substrate on opposing sides of the gate structure; and
an air gap present between the gate structure and each of the raised source region and the raised drain region, wherein the air gap separates an entire sidewall of the gate structure from the raised source region and the raised drain region.

16. The semiconductor device of claim 15, wherein the air gap comprises a gas having a dielectric constant of less than 1.5.

17. The semiconductor device of claim 15, wherein the gate structure comprising at least one gate dielectric and at least one gate conductor, the gate structure having a height ranging from 25 nm to 35 nm, and the width of the void separating a sidewall of the at least one gate conductor from a sidewall of one of the raised source region and the raised drain region ranges from 1 nm to 10 nm.

18. The semiconductor device of claim 15, wherein the air gap is encapsulated by a bridging dielectric layer that extends from an upper surface of the gate structure to an upper surface of each of the raised source region and the raised drain region.

19. The semiconductor device of claim 18, wherein the bridging dielectric layer is composed of silicon oxide or silicon nitride.
